(19) United States
(12) Patent Application Publication
(10) Pub. No.: US 2022/0005795 A1
(43) Pub. Date: Jan. 6, 2022

(54) INTEGRATED COMPONENT AND PORWER SWITCHING DEVICE

(71) Applicants: Huawei Technologies Co., Ltd., Shenzhen (CN); FRAUNHOFER-GESELLSCHAFT ZUR FÖRDERUNG DER ANGEWANDTEN FORSCHUNG E.V., Munich (DE)

(72) Inventors: Zhixiang HU, Dongguan (CN); Yujian LIN, Shenzhen (CN); Zhihua LIU, Dongguan (CN); Eckart HOENE, Berlin (DE); Wei TAN, Vienna (AT)

(21) Appl. No.: 17/480,972

(22) Filed: Sep. 21, 2021

Related U.S. Application Data
(63) Continuation of application No. PCT/EP2019/064069, filed on May 29, 2019.

(51) Int. Cl. H01L 25/16; H05K 1/18; H01L 23/00

(52) U.S. Cl. CPC H01L 25/16; H05K 1/181; H01L 24/24; H05K 2201/10015; H01L 2224/2518; H05K 2201/1003; H05K 2201/1053; H01L 24/25; H01L 2224/24265; H05K 2201/10515

(57) ABSTRACT

The present application provides an integrated device, and a power switching device comprising the integrated device. The integrated device comprises a substrate, a die arranged inside the substrate, at least one capacitor arranged on a surface of the substrate, wherein the die and the at least one capacitor are electrically connected. The power switching device comprises at least one integrated device according to the aforementioned embodiments of the present application. The compact design of the integrated device enables a high frequency, high efficiency, high power density power switching device.

### CROSS-REFERENCE TO RELATED APPLICATIONS

This application is a continuation of International Application No. PCT/EP2019/064069, filed on May 29, 2019. The disclosure of the aforementioned application is hereby incorporated by reference in their entirety.

### TECHNICAL FIELD

The present application relates to an integrated component for power conversion, and in particular, to a high frequency, high efficiency, high power density power switching device with integrated components.

### BACKGROUND

Power conversion is an important issue in many different electronic applications. Power losses limit a miniaturization of a switching mode power supply. However, how to efficiently convert power is crucial for almost every kind of power conversion. Particularly, it is desired to keep power losses, which may occur in connection with the power conversion, as low as possible, while trying to make an occupied area needed for the power conversion as small as possible.

Increasing a switching frequency is a main way to reduce area for increasing the power density. In this way, passive components like capacitors and/or magnetic components can be smaller. However, the efficiency drops, more or less, since there is more heat that needs to be dissipated. Nowadays, a typical switching frequency is around 1 MHz for a direct current to direct current (DC-DC) converter. When increasing the switching frequency, both the alternating current (AC) resistance and the switching losses will increase significantly. Thus, it is impossible to increase the switching frequency to 2 MHz, for example, if a size of the device needs to be reduced and the same efficiency needs to be maintained.

A high frequency, high efficiency, high power density switching mode power supply is thus desired.

### SUMMARY

In view of the above-mentioned problems and limitations, embodiments of the present application aim to improve the efficiency of power converters. An object is to provide a new power converter with integrated components, to provide an innovated packaging structure for enabling area saving to increase a power density.

The object is achieved by the embodiments provided in the enclosed independent claims. Advantageous implementations of the embodiments are further defined in the dependent claims.

A first aspect of the application provides an integrated device for power switching, wherein the integrated device comprises: a substrate, a die arranged inside the substrate, and at least one capacitor arranged on a surface of the substrate, wherein the die and the at least one capacitor are electrically connected.

The proposed integrated device of the first aspect employs an advanced packaging structure. In this way, area can be saved, in order to increase the power density. Further, the AC resistance is also reduced, thus improving an efficiency of the power conversion.

In an implementation form of the first aspect, the die is embedded into the substrate.

Various conventional embedding technologies can be applied to embed the bare die into the substrate.

In an implementation form of the first aspect, the substrate comprises a plurality of layers, and the die is arranged between any two layers of the substrate.

The substrate may thus have a layered structure. In particular, the substrate may comprise an even number of layers, e.g., 2 layers, 4 layers, 6 layers, or 8 layers. The die may be located between any two adjacent layers.

In an implementation form of the first aspect, each layer of the substrate is made of a metal material, particularly of copper.

In an implementation form of the first aspect, a summed up thickness of the metal material in the substrate, particularly of copper, is at least 35 μm.

Considering power losses, the thickness of the metal material, particular of the copper, should not be too thin. Thus, the above values reduce power losses.

In an implementation form of the first aspect, the at least one capacitor and the die are connected through at least one via, in particular micro via(s).

The micro via(s) particularly may be used to electrically connect the bare die and the capacitors.

In an implementation form of the first aspect, the layers of the substrate are interconnected with the at least one via.

The micro via(s) may particularly be used to electrically interconnect the layers of the substrate as well.

In an implementation form of the first aspect, a number of the layers of the substrate is equal to or less than 8.

In order to control a potential power loop in the substrate, the number of the layers of the substrate is preferably no more than 8.

In an implementation form of the first aspect, at least one capacitor is configured to route an input signal to the die, and at least one capacitor is configured to route an output signal from the die.

The capacitors on the surface of the substrate may be input capacitors or output capacitors. The input capacitor can be used to guide the input signal to the integrated component, particularly to the die of the integrated component. The output capacitor can be used to guide the output signal from the integrated component, particularly from the die of the integrated component.

A second aspect of the application provides a power switching device. In particular, the power switching device comprises at least one integrated device according to the first aspect or one of the implementation forms of the first aspect.

A power switching device working at a high frequency, with the proposed integrated components, is advantageous having increased efficiency and power density.

In an implementation form of the second aspect, the power switching device further comprises a controller, a printed circuit board, at least one magnetic component, and connection elements interconnecting all components of the power switching device.

All necessary components for implementing a power switching function may be comprised by the power switching device. Particularly, the at least one magnetic component may be a planar transformer coil.

In an implementation form of the second aspect, the at least one integrated device is attached to, in particular soldered onto, the printed circuit board of the power switching device.

In an implementation form of the second aspect, the power switching device is configured to: receive an input power signal; convert the input power signal to an output power signal; and output the output power signal.

To be able to convert a power signal, the power switching device may be required to convert an input power signal to an output power signal.

In an implementation form of the second aspect, the input power signal is received by at least one capacitor of the at least one integrated device; and the output power signal is output by at least one capacitor of the at least one integrated device.

In an implementation form of the second aspect, the power switching device is configured to operate at a switching frequency higher than 500 kHz.

In an implementation form of the second aspect, the printed circuit board comprises multiple layers, particularly at least 8 layers.

In an implementation form of the second aspect, each layer includes a metal material, particularly copper, and the summed up thickness of metal material in the printed circuit board is at least 70 μm.

It has to be noted that all devices, elements, units and means described in the present application could be implemented in software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof.

### BRIEF DESCRIPTION OF DRAWINGS

The above described aspects and implementation forms of the present application will be explained in the following description of specific embodiments in relation to the enclosed drawings, in which

FIG. 1 shows an integrated device according to an embodiment of the present application.

FIG. 2 shows another integrated device according to an embodiment of the present application.

FIG. 3 shows a power switching device according to an embodiment of the present application.

FIG. 4 shows an improvement on arrangement of switch devices and capacitors according to an embodiment of the present application.

FIG. 5 shows an area reduction of a power switching device based on LLC topology according to an embodiment of the present application.

FIG. 6 shows an area reduction of a power switching device based on multi-cell LLC topology according to an embodiment of the present application.

### DETAILED DESCRIPTION OF EMBODIMENTS

The embodiments of the present application provide an improved power switching device, including integrated components for enabling a highly compact and efficient design.

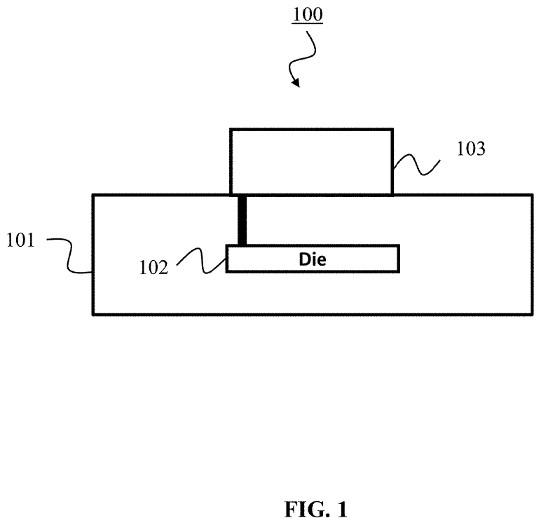

FIG. 1 shows a design of an integrated device 100 for power switching, according to an embodiment of the application. The integrated device 100 comprises a substrate 101, a die 102, and at least one capacitor 103. In particular, the die 102 is arranged inside the substrate 101. The at least one capacitor 103 is arranged on a surface of the substrate 101. Further, the die 102 and the at least one capacitor 103 are electrically connected.

Optionally, the die 102 may be embedded into the substrate 101 according to an embodiment of the application. Optionally, the substrate 101 may comprise a plurality of layers, and the die 102 is arranged between any two layers of the substrate 101. Usually, the substrate 101 according to an embodiment of the application comprises at least 2 layers. For instance, the die 102 may be embedded between the middle two layers of the substrate 101.

In particular, each layer of the substrate 101 according to an embodiment of the application may be made of a metal material, particularly of copper. For the consideration of minimizing the power loss, a thickness of the metal material should not be too thin. Optionally, a summed up thickness of the metal material in the substrate, particularly of copper, is thus at least 35 μm.

Optionally, the at least one capacitor 103 and the die 102 may be connected through at least one via, in particular at least one micro via. In addition, the layers of the substrate 101 may be interconnected with at least one via. The via, which interconnects the layers of the substrate 101, may be a different via than the via connecting the die 102 and the at least one capacitor 103. Such a design significantly shortens the wiring required for a traditional power converter. Possibly, the same via may be used to connect the die 102 and the at least one capacitor 103, and to interconnect the multiple layers of the substrate 101.

Optionally, a number of the layers of the substrate 101 may be equal to or less than 8. In order to better control a power loop in the device, the substrate 101 of the integrated device 100 according to an embodiment of the application is suggested to comprise no more than 8 layers.

Optionally, at least one capacitor 103 may be configured to route an input signal to the die 102. Accordingly, at least one capacitor 103 may be configured to route an output signal from the die 102. The at least one capacitor 103 of the integrated device 100, according to an embodiment of the application, may be an input capacitor, or an output capacitor. The input capacitor may receive the input signal, and route the signal to the die 102 embedded in the substrate 101. Particularly, the input signal may be routed through the at least one via connecting the die 102 and the at least one capacitor 103. Similarly, the output capacitor may route the output signal from the die 102 embedded in the substrate 101, and output the output signal. Particularly, the output signal may be routed through the at least one via connecting the die 102 and the at least one capacitor 103 as well.

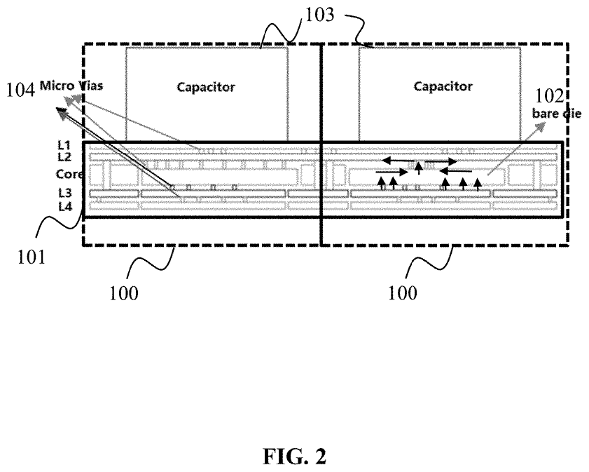

FIG. 2 shows in more detail an example of the integrated device 100 according to an embodiment of the present application. In particular, as shown in FIG. 2, two integrated devices 100 may be arranged side-by-side. The substrate 101 comprises 4 layers (L1/L2/L3/L4). Each of the dies 102 of the two integrated devices 100 is a bare die embedded in the same substrate 101. In particular, each of the dies 102 is embedded in a core, wherein the core may be made of a prepreg material. Different embedding technologies may be applied herein. In this implementation, the die 102 is exemplarily arranged between a second layer L2 and a third layer L3 of the substrate 101. A plurality of micro vias are used to electrically connect each of the dies 102 to the respective capacitor 103 of the same integrated device 100.

As shown in FIG. 2, arrows between the substrate 101 and the die 102 are current flows from the die 102 to the capacitor 103. The presence of lateral current flows can be observed. In fact, in such an integrated component, lateral current flow is hardly avoidable. In this implementation, the substrate 101 is made of copper. For the consideration of minimizing power loss, the thickness of copper in the substrate 101 should not be too thin, thus may at least be 35 μm. Besides, it is also suggested to control power loop. Therefore, the substrate 101 of such integrated component 100 may comprise equal to or less than below 8 layers.

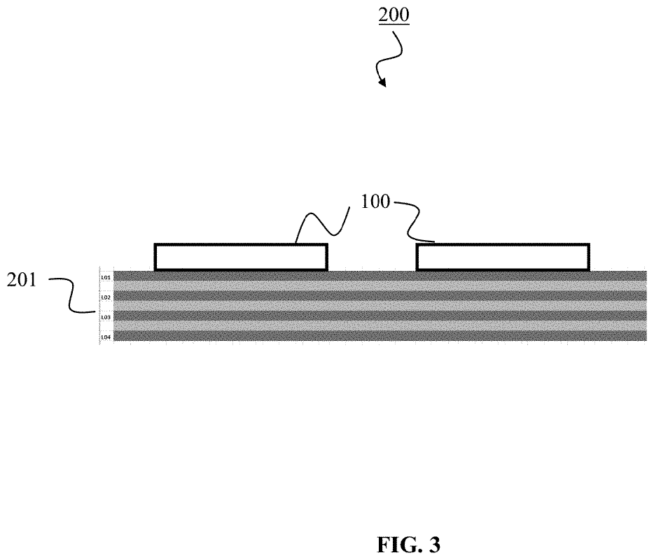

A power switching device 200, according to an embodiment of the application, may be employed with at least one integrated device 100, as shown in FIG. 1 or FIG. 2. Such design enables a highly compact and efficient power switching device. The power switching device 200 may also comprise a controller, a printed circuit board 201 as shown in FIG. 3, at least one magnetic component, and connection elements interconnecting all components of the power switching device.

In particular, all necessary components, in order to implement a power switching function, should be integrated in the power switching device 200. In one implementation, the at least one magnetic component may be a planar transformer coil, which is arranged on top of the printed circuit board 201.

FIG. 3 shows an exemplary power switching device 200 according to an embodiment of the present application. Optionally, on top of the printed circuit board 201 of the power switching device 200, two integrated devices 100 are arranged as depicted in FIG. 3. The integrated device 100 may be attached to the printed circuit board 201. In particular, the integrated device 100 may be soldered onto the printed circuit board 201.

To convert a power signal, the power switching device 200, according to an embodiment of the application, can be configured to convert an input power signal to an output power signal.

Optionally, the input power signal is received by at least one capacitor 103 of at least one integrated device 100 of the power switching device 200. Optionally, the output power signal is output by at least one capacitor 103 of at least one integrated device 100 of the power switching device 200. In particular, the power switching device 200 receives the input power signal using an input capacitor of one integrated device 100. The input power signal may be routed by the input capacitor of the integrated device 100 to the respective die 102 of the integrated device 100. The input power signal may pass through a transformer of the power switching device 200, to become an output power signal. The output power signal is further routed by an output capacitor of another integrated device 100 from the respective die 102 of the integrated device 100. Then the power switching device 200 outputs the converted output power signal. It should be noted that, the integrated device 100 comprising the input capacitor and the integrated device 100 comprising the output capacitor, may be different integrated devices.

Optionally, the power switching device 200, according to an embodiment of the application, may operate at a switching frequency higher than 500 kHz.

Optionally, the printed circuit board 201 of the power switching device 200, according to an embodiment of the application, may comprise a plurality of layers. Particularly, the printed circuit board 201 may comprise at least 8 layers. Optionally, each layer of the printed circuit board 201 may include a metal material, particularly copper. For instance, the summed up thickness of metal material of each layer in the printed circuit board 201 is at least 70 μm.

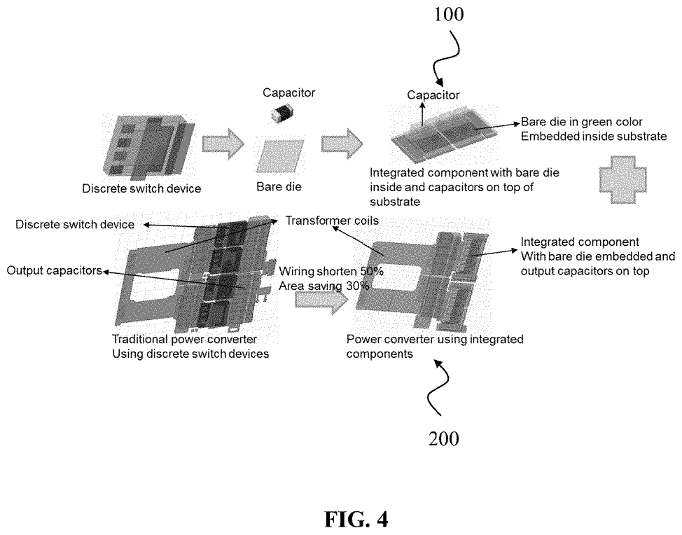

FIG. 4 shows an improved arrangement of switch devices and capacitors according to an embodiment of the present application. A discrete switch device shown in the left part of FIG. 4 may be used in a traditional power converter device. Instead of using the discrete switch devices, embodiments of the present application propose to employ the integrated device 100 with the bare die 102 inside a substrate 101 and capacitors 103 on top of the substrate 101. A power converter with such an arrangement is highly beneficial. As an example shown in FIG. 4, wiring can be shortened by around 50%, and an area saving can be up to 30% with such a design.

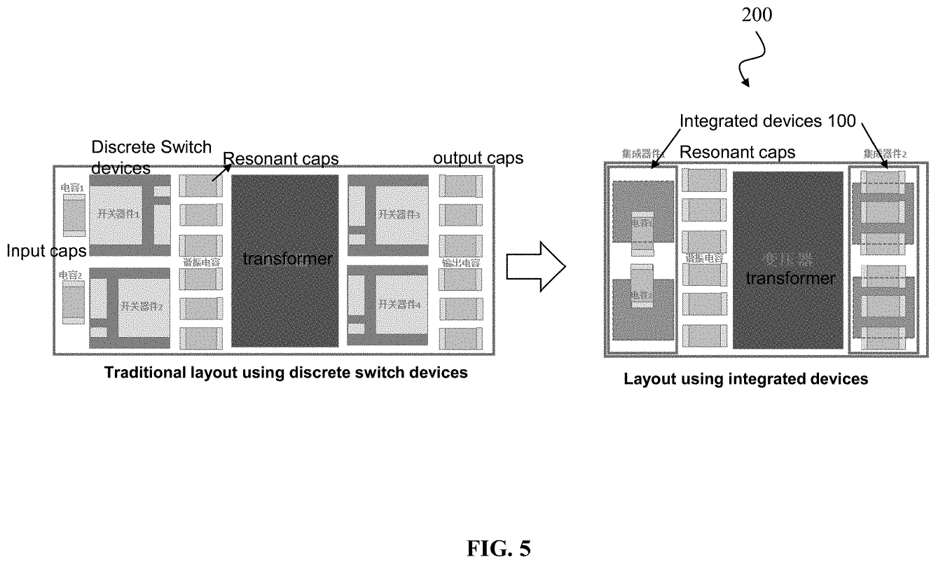

FIG. 5 shows a comparison of the layout using discrete switch devices and using integrated devices 100. In particular, FIG. 5 shows layouts of the power switching devices based on an LLC topology (a resonant half-bridge converter that uses two inductors (LL) and a capacitor (C), refers to the LLC topology).

The power switching device 200, according to an embodiment of the application, may comprise a plurality of integrated devices 100 with input capacitors and a plurality of integrated devices 100 with output capacitors. The plurality of integrated devices 100 with input capacitors may be arranged at one side of the power switching device 200. The plurality of integrated devices 100 with output capacitors may be arranged at another side of the power switching device 200.

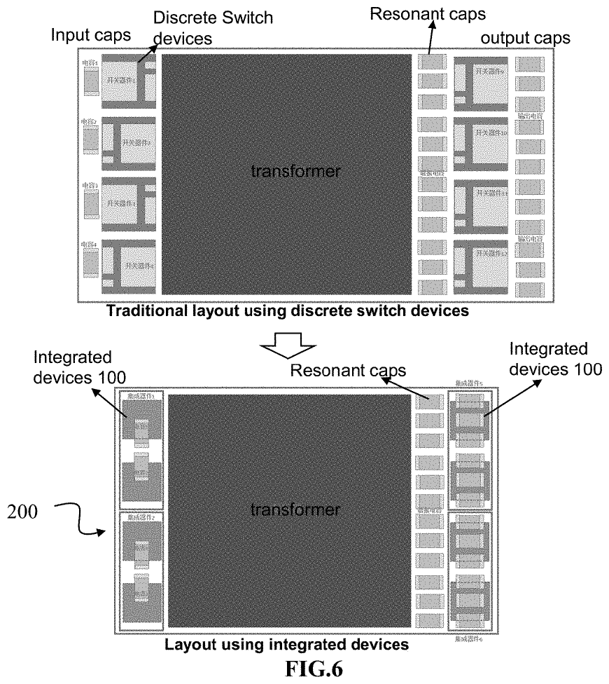

FIG. 6 also shows a comparison of the layout using discrete switch devices and using integrated devices 100. In particular, FIG. 6 shows layouts of the power switching devices based on a multi-cell LLC topology.

Notably, the power switching devices 200 with integrated devices 100 are more compact. That is, the areas required for these devices 200 are reduced. Further, a shorter high frequency power loop, and a lower AC resistance are achieved. Compared with the traditional design using discrete switch devices, the embodiments of the present application increase an efficiency and power density for power conversion.

The present application has been described in conjunction with various embodiments as examples as well as implementations. However, other variations can be understood and effected by those persons skilled in the art and practicing the claimed application, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

1. The integrated device for power switching, wherein the integrated device comprises:
a substrate,
a die embedded in the substrate,
at least one capacitor arranged on a surface of the substrate,
wherein the die and the at least one capacitor are electrically connected.

2. The integrated device according to claim 1, wherein
the die embedded in a core of the substrate.

3. The integrated device according to claim 1, wherein
the substrate comprises a plurality of layers, and
the die is arranged between any two layers of the substrate.

4. The integrated device according to claim 3, wherein
each layer of the substrate is made of a metal material.

5. The integrated device according to claim 4, wherein
a summed up thickness of the metal material in the substrate is at least 35 μm.

6. The integrated device according to claim 1, wherein
the at least one capacitor and the die are connected through at least one via.

7. The integrated device according to claim 3, wherein
the layers of the substrate are interconnected with a plurality of micro vias.

8. The integrated device according to claim 3, wherein
a number of the layers of the substrate is equal to or less than 8.

9. The integrated device according to claim 1, wherein
a first capacitor of the at least one capacitor is configured to route an input signal to the die, and
a second capacitor of the at least one capacitor is configured to route an output signal from the die.

10. A power switching device comprising:
at least one integrated device according to claim 1.

11. The power switching device according to claim 10, further comprising:
a number of components including a controller, a printed circuit board, at least one magnetic component, and connection elements interconnecting the number of components of the power switching device.

12. The power switching device according to claim 10, wherein
the at least one integrated device is attached to the printed circuit board of the power switching device.

13. The power switching device according to claim 10, configured to:
receive an input power signal;
convert the input power signal to an output power signal by the at least one integrated device; and
output the output power signal.

14. The power switching device according to claim 13, wherein
the input power signal is received by at least one capacitor of the at least one integrated device; and
the output power signal is output by at least one capacitor of the at least one integrated device.

15. The power switching device according to claim 10, wherein the power switching device is configured to:
operate at a switching frequency of at least 500 kHz.

16. The power switching device according to claim 11, wherein:
the printed circuit board comprises multiple layers.

17. The power switching device according to claim 16, wherein
each layer includes a metal material and the summed up thickness of metal material of the multiple layers in the printed circuit board is at least 70 μm.
